(19) United States
(12) Patent Application Publication
(10) Pub. No.: US 2024/0429887 A1
(43) Pub. Date: Dec. 26, 2024

(54) OPERATIONAL TRANSCONDUCTANCE AMPLIFIER WITH BOOSTED TRANSCONDUCTANCE

(71) Applicant: QUALCOMM Incorporated, San Diego, CA (US)

(72) Inventors: Chieh-Yu HSIEH, Irvine, CA (US); Behnam SEDIGHI, La Jolla, CA (US)

(21) Appl. No.: 18/339,111

(22) Filed: Jun. 21, 2023

(51) Int. Cl. H03F 3/45

(52) U.S. Cl. CPC H03F 3/45179; H03F 2203/45024; H03F 2203/45288

(57) ABSTRACT

Certain aspects of the present disclosure generally relate to electronic circuits and, more particularly, to an operational transconductance amplifier (OTA). One example amplifier generally includes: a first pair of input transistors; a first pair of cascode transistors coupled in cascode with the first pair of input transistors, respectively; a second pair of input transistors; a second pair of cascode transistors coupled in cascode with the second pair of input transistors, respectively; and a third pair of input transistors coupled to the second pair of cascode transistors, respectively.

### TECHNICAL FIELD

Certain aspects of the present disclosure generally relate to electronic circuits and, more particularly, to an operational transconductance amplifier (OTA).

### BACKGROUND

An operational transconductance amplifier (OTA) is an amplifier that generates an output current based on an input voltage. For example, a differential input voltage for the OTA may produce an output current. In effect, the OTA may be a voltage-controlled current source. An OTA is widely used to implement various circuit functions. For example, an OTA may be used to implement a discrete-time or continuous-time integrator or voltage buffers.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects are directed toward an amplifier. The amplifier generally includes: a first pair of input transistors; a first pair of cascode transistors coupled in cascode with the first pair of input transistors, respectively; a second pair of input transistors; a second pair of cascode transistors coupled in cascode with the second pair of input transistors, respectively; and a third pair of input transistors coupled to the second pair of cascode transistors, respectively.

Certain aspects are directed toward an amplifier. The amplifier generally includes: a first transconductance (Gm) path coupled between a differential output pair, the first Gm path including a first pair of input transistors and a first pair of cascode transistors coupled in cascode with the first pair of input transistors, respectively; a second Gm path coupled between the differential output pair, the second Gm path including a second pair of input transistors and a second pair of cascode transistors coupled in cascode with the second pair of input transistors, respectively; and a third Gm path comprising a third pair of input transistors, the third Gm path being coupled to the second pair of cascode transistors.

Certain aspects are directed toward a method for signal amplification. The method generally includes: receiving differential input signals at respective gates of a first pair of input transistors, respective gates of a second pair of input transistors, and respective gates of a third pair of input transistors, wherein: a first pair of cascode transistors are coupled in cascode with the first pair of input transistors, respectively; a second pair of cascode transistors are coupled in cascode with the second pair of input transistors, respectively; and the third pair of input transistors are coupled to the second pair of cascode transistors, respectively; and generating differential output signals at a differential output pair, respectively, based on the differential input signals, wherein the differential output pair is coupled to the first pair of cascode transistors, respectively.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates a block diagram of an example device, in which aspects of the present disclosure may be practiced.

FIG. 2 illustrates an example operational transconductance amplifier (OTA), in accordance with certain aspects of the present disclosure.

FIG. 3 illustrates an OTA implemented with separate current sources for Gm paths, in accordance with certain aspects of the present disclosure.

FIG. 4 is a flow diagram illustrating example operations for signal amplification, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure provide techniques and apparatus for signal amplification via an operational transconductance amplifier (OTA). The OTA may implemented with three transconductance (Gm) paths, in some aspects. A first Gm path may include a first pair of input transistors coupled to a respective first pair of cascode transistors and a second Gm path may include a second pair of input transistors coupled to a respective second pair of cascode transistors. A third Gm path may include a third pair of input transistors coupled to the second pair of cascode transistors. With three Gm paths, the transconductance for the OTA may be increased (e.g., boosted) as compared to some conventional implementations, allowing for increased speed and reduced noise for the OTA. The OTA described herein allows for a reduction in the size of active load transistors as compared to some conventional implementations, providing higher output impedance and improved direct-current (DC) gain.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

As used herein, an “activation state” of a transistor generally refers to whether the transistor is turned on (e.g., biased in an activated state) or turned off (e.g., biased in a deactivated state).

### An Example Device

It should be understood that aspects of the present disclosure may be used in a variety of applications. Although the present disclosure is not limited in this respect, the circuits disclosed herein may be used in any of various suitable apparatuses, such as in the power supply, battery charging circuit, or power management circuit of a communication system, a video codec, audio equipment such as music players and microphones, a television, camera equipment, and test equipment such as an oscilloscope. Communication systems intended to be included within the scope of the present disclosure include, by way of example only, cellular radiotelephone communication systems, satellite communication systems, two-way radio communication systems, one-way pagers, two-way pagers, personal communication systems (PCS), personal digital assistants (PDAs), and the like.

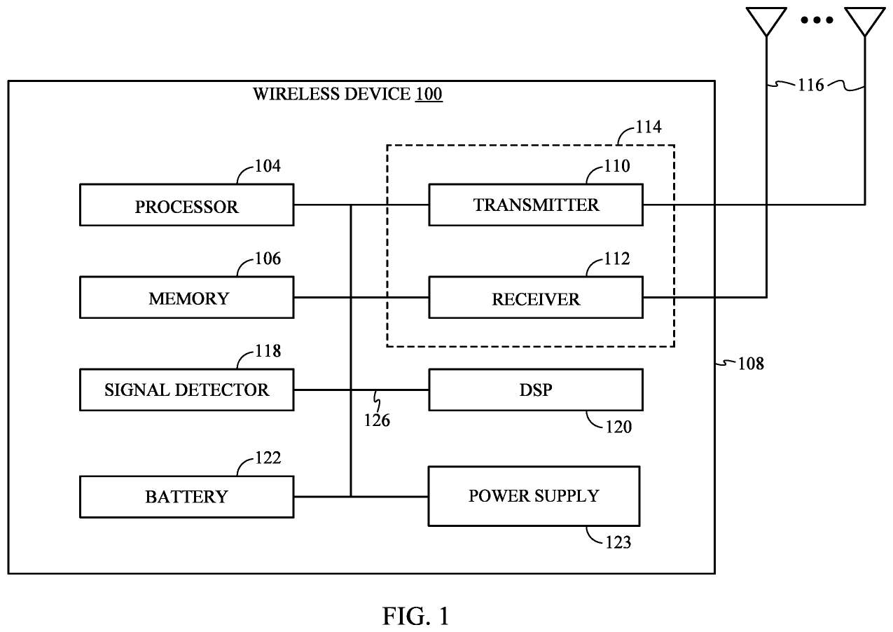

FIG. 1 illustrates an example device 100 in which aspects of the present disclosure may be implemented. The device 100 may be a battery-operated device such as a cellular phone, a PDA, a handheld device, a wireless device, a laptop computer, a tablet, a smartphone, an Internet of things (IoT) device, a wearable device, a virtual reality (VR) or augmented reality (AR) device, etc.

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106.

In certain aspects, the device 100 may also include a housing 108 that may include a transmitter 110 and a receiver 112 to allow transmission and reception of data between the device 100 and a remote location. For certain aspects, the transmitter 110 and receiver 112 may be combined into a transceiver 114. One or more antennas 116 may be attached or otherwise coupled to the housing 108 and electrically connected to the transceiver 114. The device 100 may also include (not shown) multiple transmitters, multiple receivers, and/or multiple transceivers.

The device 100 may also include a signal detector 118 that may be used in an effort to detect and quantify the level of signals received by the transceiver 114. The signal detector 118 may detect such signal parameters as total energy, energy per subcarrier per symbol, and power spectral density, among others. The device 100 may also include a digital signal processor (DSP) 120 for use in processing signals.

The device 100 may further include a battery 122, which may be used to power the various components of the device 100 (e.g., when the device is disconnected from an external power source). The device 100 may also include a power supply system 123 for managing the power from the battery (or from one or more power ports for receiving external power) to the various components of the device 100. At least a portion of the power supply system 123 may be implemented in one or more power management integrated circuits (power management ICs or PMICs) The power supply system 123 may perform a variety of functions for the device 100 such as DC-to-DC conversion, battery charging, power-source selection, voltage scaling, power sequencing, etc.

In some aspects, one or more functions for the device 100 may be implemented using an operational transconductance amplifier (OTA). An OTA generally refers to an amplifier that converts a voltage at an input of the OTA to a current provided to an output of the OTA. For example, an OTA may be used to implement any of various suitable circuits for the device, such as variable discrete-time integrators, continuous-time integrators, or voltage buffers.

The various components of the device 100 may be coupled together by a bus system 126, which may include a power bus, a control signal bus, and/or a status signal bus in addition to a data bus. Additionally or alternatively, various combinations of the components of the device 100 may be coupled together by one or more other suitable techniques.

### Example Operational Transconductance Amplifier (OTA)

Certain aspects of the present disclosure are directed towards an operational transconductance amplifier (OTA) with higher speed and higher direct-current (DC) gain as compared to at least some conventional implementations. The OTA described herein provides increased accuracy and fast settling time. Without sufficient transconductance (Gm) for an OTA, the operating speed of circuitry using the OTA may suffer. Moreover, OTA noise may increase if the OTA input pair does not provide enough transconductance. In some implementations, the OTA may be designed with high Gm, but at the cost of increased power consumption. For instance, the OTA may be biased with high current for increased Gm, which may result in increased power consumption and other undesired consequences such as lower DC gain, increased area, or increased parasitics at internal nodes of the OTA.

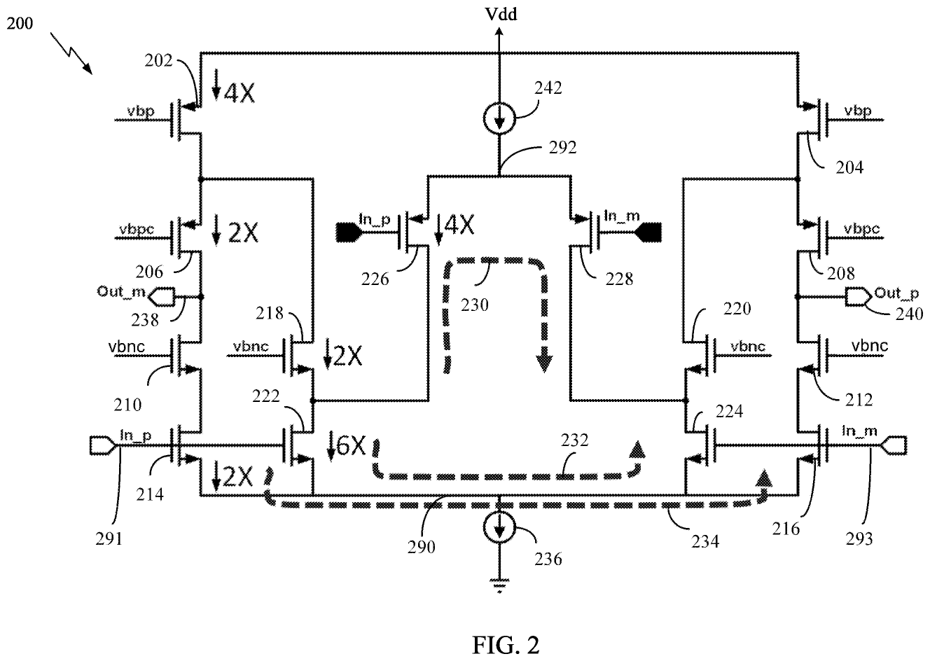

FIG. 2 illustrates an example OTA 200, in accordance with certain aspects of the present disclosure. As shown, the OTA 200 includes a p-channel metal-oxide-semiconductor (PMOS) transistor 202 and a PMOS transistor 204 having sources coupled to a voltage rail Vdd. Also referred to as “active load transistors,” the PMOS transistors 202, 204 may be biased via a PMOS bias voltage (labeled “vbp”). The OTA 200 may also include a PMOS transistor 206 with a source coupled to a drain of transistor 202 and a PMOS transistor 208 with a source coupled to a drain of transistor 204. The PMOS transistors 206, 208 may be referred to as cascode transistors coupled in cascode with the transistors 202, 204, respectively. The PMOS transistors 206, 208 may be biased via a cascode PMOS bias voltage (labeled “vbpc”). The drain of transistor 206 may be coupled to a negative output 238 (labeled “Out_m”) of an output pair, and the drain of transistor 208 may be coupled to a positive output 240 (labeled “Out_p”) of the output pair. The positive output 240 and the negative output 238 form a differential output pair of the OTA 200, for outputting a differential output current signal.

A drain of an n-channel metal-oxide-semiconductor (NMOS) transistor 210 may be coupled to the negative output 238, and a drain of an NMOS transistor 212 may be coupled to the positive output 240. The NMOS transistors 210, 212 may be referred to as cascode transistors coupled in cascode with the transistors 214, 216, respectively. The transistors 210, 212 may be biased via a cascode NMOS bias voltage (labeled “vbnc”). A source of NMOS transistor 210 may be coupled to a drain of an input NMOS transistor 214, and a source of NMOS transistor 212 may be coupled to a drain of an input NMOS transistor 216. As shown, a positive input 291 (e.g., labeled “In_p”) may be coupled to a gate of the input transistor 214, and a negative input 293 (e.g., labeled “In_m”) may be coupled to a gate of the input transistor 216. The positive input 291 and the negative output 293 form a differential input pair of the OTA 200, for receiving a differential input voltage signal. Sources of NMOS transistors 214, 216 may be coupled to a current source 236, as shown. The current source 236 sinks a current from node 290 coupled to the sources of input transistors 214, 216.

The OTA 200 includes a first Gm path 234 from the negative output 238 across transistor 210, transistor 214, transistor 216, and transistor 212 to the positive output 240, as shown. As shown, alternating current (AC) may flow from the negative output 238 across transistor 210, transistor 214, transistor 216, and transistor 212 to the positive output 240.

In some aspects, the OTA 200 may be implemented with a second Gm path 232. For example, the OTA 200 may include an NMOS transistor 218 having a drain coupled to a drain of PMOS transistor 202 and an NMOS transistor 220 having a drain coupled to a drain of PMOS transistor 204. The gates of transistors 218, 220 may be biased via the cascode NMOS bias voltage (vbnc). A source of NMOS transistor 218 may be coupled to a drain of an NMOS input transistor 222, and a source of NMOS transistor 220 may be coupled to a drain of an NMOS input transistor 224. The NMOS transistors 218, 220 may be referred to as cascode transistors coupled in cascode to the transistors 222, 224, respectively. As shown, the positive input (In_p) may be coupled to a gate of the input transistor 222, and the negative input (In_m) may be coupled to a gate of the input transistor 224. The sources of NMOS input transistors 222, 224 may be coupled to the current source 236. Thus, the second Gm path 232 may exist for alternating current flow from the negative output 238, across transistor 206, transistor 218, input transistor 222, input transistor 224, transistor 220, and transistor 208 to the positive output 240.

In certain aspects of the present disclosure, the OTA 200 may also include a third Gm path 230 by implementing a complementary metal-oxide-semiconductor (CMOS) input pair. For example, the OTA 200 may include PMOS input transistors 226, 228 having sources coupled to a current source 242. The current source 242 sources a current to a node 292 coupled to the sources of input transistors 226, 228, as shown. The positive input (In_p) may be coupled to a gate of input transistor 226, and the negative input (In_m) may be coupled to a gate of input transistor 228. Drains of input transistors 226, 228 may be coupled to drains of NMOS input transistors 222, 224, respectively. Thus, the third Gm path 230 may exist from the negative output 238, across transistor 206, transistor 218, transistor 226, transistor 228, transistor 220, and transistor 208 to the positive output 240.

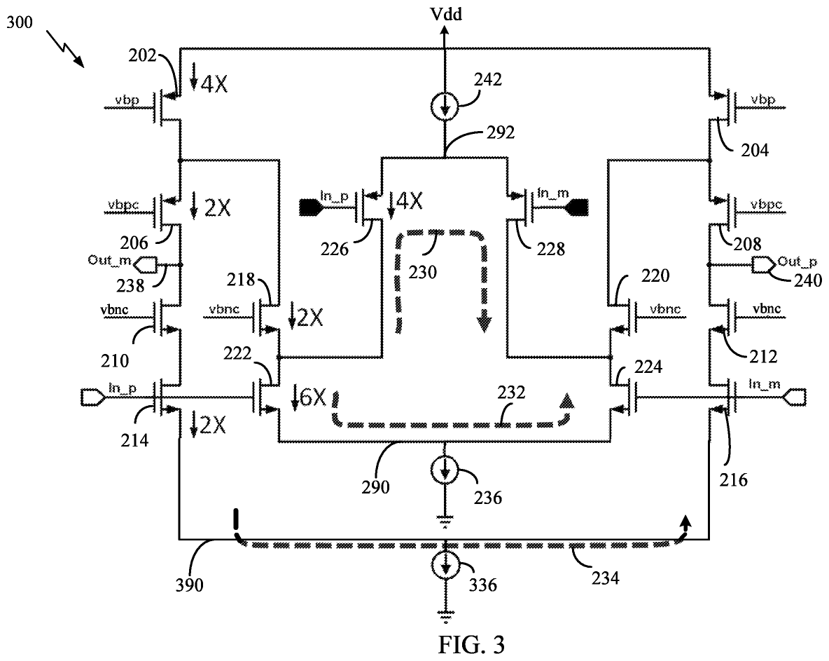

FIG. 3 illustrates an OTA 300 implemented with separate current sources for the first and second Gm paths, in accordance with certain aspects of the present disclosure. For example, the current source 236 may sink a current from node 290 which may be coupled to the sources of input transistors 222, 224, as shown. Another current source 336 may be configured to sink a current from node 390 coupled to the sources of the input transistors 214, 216. Thus, the first Gm path 234 may include node 390 between input transistors 214, 216, and the second Gm path 232 may include node 290 between input transistors 222, 224.

Implementing the third Gm path 230 (as shown in either FIG. 2 or 3) results in an increased transconductance for the OTA 200 as compared to some conventional implementations, allowing for increased speed and reduced noise for the OTA. Moreover, active load transistors may be reduced in size as compared to some conventional implementations, providing higher output impedance and improved direct-current (DC) gain. For instance, a factor of four (“4×”) of direct current (e.g., four times a unit of current) may flow across transistor 202. A factor of two (“2×”) of direct current may flow across transistor 206, and a factor of two of direct current may flow across transistor 218. In other words, half the current across transistor 202 may flow through transistor 206, and the other half of the current across transistor 202 may flow through transistor 218, as shown. A factor of four of current may also flow across input transistor 226. Therefore, the sum of currents across transistors 218, 226 may flow across transistor 222 (e.g., a factor of six (“6×”) of current may flow across transistor 222). The size of the active load transistors (e.g., transistors 202, 204) may be reduced as compared to an implementation without the third Gm path 230 (e.g., without PMOS transistor 226), providing higher output impedance and greater DC gain (e.g., improved by 8 dB). Moreover, the third Gm path may increase (e.g., boosted) the OTA transconductance (e.g., by 50%) while consuming the same power as compared to an implementation without the third Gm path. The settling time of the OTA 200 is also decreased (e.g., by 20%) due to a wider feedback loop bandwidth when the OTA 200 is used to implement a discrete-time integrator.

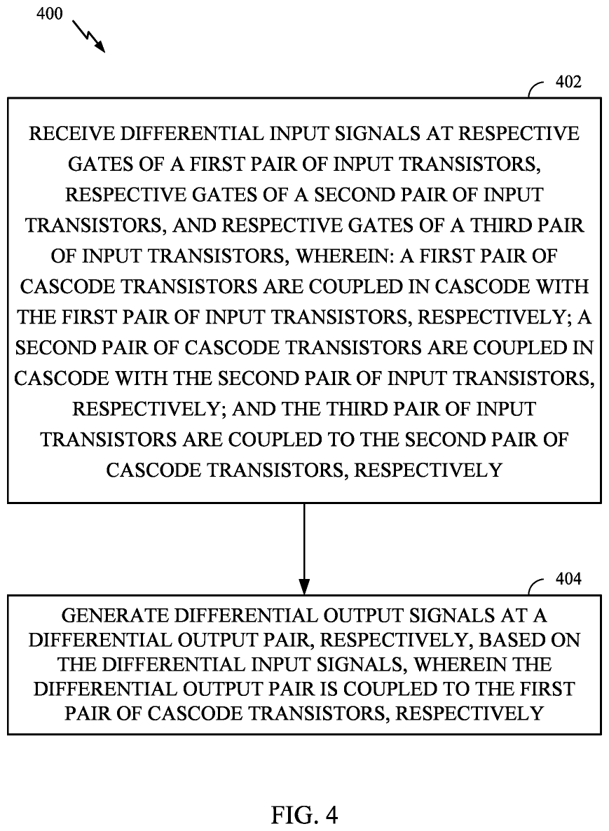

FIG. 4 is a flow diagram illustrating example operations 400 for signal amplification, in accordance with certain aspects of the present disclosure. The operations 400 may be performed by an OTA, such as the OTA 200 or 300.

At block 402, the OTA receives differential input signals at respective gates of a first pair of input transistors (e.g., input transistors 214, 216), respective gates of a second pair of input transistors (e.g., input transistors 222, 224), and respective gates of a third pair of input transistors (e.g., input transistors 226, 228). A first pair of cascode transistors (e.g., transistors 210, 212) may be coupled in cascode with the first pair of input transistors, respectively. A second pair of cascode transistors (e.g., transistors 218, 220) may be coupled in cascode with the second pair of input transistors, respectively. The third pair of input transistors may be coupled to the second pair of cascode transistors, respectively.

At block 404, the OTA may generate differential output signals at a differential output pair (e.g., outputs 238, 240), respectively, based on the differential input signals. In some aspects, the differential output pair may be coupled to the first pair of cascode transistors, respectively.

In some aspects, a first transistor (e.g., transistor 206) of a fourth pair of cascode transistors (e.g., transistors 206, 208) may be coupled to a first transistor (e.g., transistor 202) of a pair of bias transistors (e.g., transistors 202, 204). A second transistor (e.g., transistor 208) of the fourth pair of cascode transistors may be coupled to a second transistor (e.g., transistor 204) of the pair of bias transistors.

In some aspects, sources of the pair of bias transistors are coupled to a voltage rail (e.g., Vdd). In some aspects, a first transistor (e.g., transistor 218) of the second pair of cascode transistors may be coupled to a drain of a first transistor (e.g., transistor 202) of the pair of bias transistors. A second transistor (e.g., transistor 220) of the second pair of cascode transistors may be coupled to a drain of a second transistor (e.g., transistor 204) of the pair of bias transistors.

In some aspects, a drain of a first transistor (e.g., transistor 210) of the first pair of cascode transistors is coupled to a negative output (Out_m) of the differential output pair. In some aspects, a drain of a second transistor (e.g., transistor 212) of the first pair of cascode transistors is coupled to a positive output (e.g., Out_p) of the differential output pair.

In some aspects, a positive input (e.g., In_p) of a differential input pair may be coupled to gates of a first transistor (e.g., transistors 214, 222, 226) of each of the first pair of input transistors, the second pair of input transistors; and the third pair of input transistors. A negative input of the differential input pair may be coupled to gates of a second transistor (e.g., transistors 216, 224, 228) of each of the first pair of input transistors, the second pair of input transistors; and the third pair of input transistors.

In some aspects, the first pair of cascode transistors, the first pair of input transistors, the second pair of cascode transistors, and the second pair of input transistors may be NMOS transistors. The third pair of input transistors may be PMOS transistors.

In some aspects, the OTA may sink (e.g., via a current source 236) a current from a node coupled to the first pair of input transistors and the second pair of input transistors. In some aspects, the OTA may source a current, via a current source (e.g., current source 242), to a node coupled to the third pair of input transistors. In some aspects, the first pair of input transistors are part of a first Gm path (e.g., the first Gm path 234), the second pair of input transistors are part of a second Gm path (e.g., the second Gm path 232), and the third pair of input transistors are part of a third Gm path (e.g., the third Gm path 230).

### Example Aspects

In addition to the various aspects described above, specific combinations of aspects are within the scope of the disclosure, some of which are detailed below:

Aspect 1: An amplifier, comprising: a first pair of input transistors; a first pair of cascode transistors coupled in cascode with the first pair of input transistors, respectively; a second pair of input transistors; a second pair of cascode transistors coupled in cascode with the second pair of input transistors, respectively; and a third pair of input transistors coupled to the second pair of cascode transistors, respectively.

Aspect 2: The amplifier of Aspect 1, further comprising: a pair of bias transistors; and a fourth pair of cascode transistors, wherein: a first transistor of the fourth pair of cascode transistors is coupled to a first transistor of the pair of bias transistors; and a second transistor of the fourth pair of cascode transistors is coupled to a second transistor of the pair of bias transistors.

Aspect 3: The amplifier of Aspect 2, wherein sources of the pair of bias transistors are coupled to a voltage rail.

Aspect 4: The amplifier of Aspect 2 or 3, wherein: a first transistor of the second pair of cascode transistors is coupled to a drain of a first transistor of the pair of bias transistors; and a second transistor of the second pair of cascode transistors is coupled to a drain of a second transistor of the pair of bias transistors.

Aspect 5: The amplifier according to any of Aspects 2-4, wherein: a drain of a first transistor of the first pair of cascode transistors is coupled to a negative output of a differential output pair of the amplifier; and a drain of a second transistor of the first pair of cascode transistors is coupled to a positive output of the differential output pair of the amplifier.

Aspect 6: The amplifier according to any of Aspects 1-5, wherein: a positive input of a differential input pair is coupled to gates of a first transistor of each of the first pair of input transistors, the second pair of input transistors; and the third pair of input transistors; and a negative input of the differential input pair is coupled to gates of a second transistor of each of the first pair of input transistors, the second pair of input transistors; and the third pair of input transistors.

Aspect 7: The amplifier according to any of Aspects 1-6, wherein: the first pair of cascode transistors, the first pair of input transistors, the second pair of cascode transistors, and the second pair of input transistors are n-channel metal-oxide-semiconductor (NMOS) transistors; and the third pair of input transistors are p-channel metal-oxide-semiconductor (PMOS) transistors.

Aspect 8: The amplifier according to any of Aspects 1-7, further comprising a current source coupled to the first pair of input transistors and the second pair of input transistors.

Aspect 9: The amplifier according to any of Aspects 1-8, further comprising a current source coupled to the third pair of input transistors.

Aspect 10: The amplifier according to any of Aspects 1-9, wherein: the first pair of input transistors are part of a first transconductance (Gm) path; the second pair of input transistors are part of a second Gm path; and the third pair of input transistors are part of a third Gm path.

Aspect 11: An amplifier, comprising: a first transconductance (Gm) path coupled between a differential output pair, the first Gm path including a first pair of input transistors and a first pair of cascode transistors coupled in cascode with the first pair of input transistors, respectively; a second Gm path coupled between the differential output pair, the second Gm path including a second pair of input transistors and a second pair of cascode transistors coupled in cascode with the second pair of input transistors, respectively; and a third Gm path comprising a third pair of input transistors, the third Gm path being coupled to the second pair of cascode transistors.

Aspect 12: The amplifier of Aspect 11, further comprising: a pair of bias transistors coupled to the second Gm path and the second Gm path; and a fourth pair of cascode transistors, wherein: a first transistor of the fourth pair of cascode transistors is coupled to a first transistor of the pair of bias transistors; and a second transistor of the fourth pair of cascode transistors is coupled to a second transistor of the pair of bias transistors.

Aspect 13: The amplifier of Aspect 12, wherein sources of the pair of bias transistors are coupled to a voltage rail.

Aspect 14: The amplifier of Aspect 12 or 13, wherein: a first transistor of the second pair of cascode transistors is coupled to a drain of a first transistor of the pair of bias transistors; and a second transistor of the second pair of cascode transistors is coupled to a drain of a second transistor of the pair of bias transistors.

Aspect 15: The amplifier according to any of Aspects 12-14, wherein: a drain of a first transistor of the first pair of cascode transistors is coupled to a negative output of the differential output pair of the amplifier; and a drain of a second transistor of the first pair of cascode transistors is coupled to a positive output of the differential output pair of the amplifier.

Aspect 16: The amplifier according to any of Aspects 11-15, wherein: a positive input of a differential input pair is coupled to gates of a first transistor of each of the first pair of input transistors, the second pair of input transistors; and the third pair of input transistors; and a negative input of the differential input pair is coupled to gates of a second transistor of each of the first pair of input transistors, the second pair of input transistors; and the third pair of input transistors.

Aspect 17: The amplifier according to any of Aspects 11-16, wherein: the first pair of cascode transistors, the first pair of input transistors, the second pair of cascode transistors, and the second pair of input transistors are n-channel metal-oxide-semiconductor (NMOS) transistors; and the third pair of input transistors are p-channel metal-oxide-semiconductor (PMOS) transistors.

Aspect 18: The amplifier according to any of Aspects 11-17, further comprising a current source coupled to the first Gm path and the second Gm path.

Aspect 19: The amplifier according to any of Aspects 11-18, further comprising a current source coupled to the third Gm path.

Aspect 20: A method for signal amplification, comprising: receiving differential input signals at respective gates of a first pair of input transistors, respective gates of a second pair of input transistors, and respective gates of a third pair of input transistors, wherein: a first pair of cascode transistors are coupled in cascode with the first pair of input transistors, respectively; a second pair of cascode transistors are coupled in cascode with the second pair of input transistors, respectively; and the third pair of input transistors are coupled to the second pair of cascode transistors, respectively; and generating differential output signals at a differential output pair, respectively, based on the differential input signals, wherein the differential output pair is coupled to the first pair of cascode transistors, respectively.

Aspect 21: The method of Aspect 20, wherein: a first transistor of a fourth pair of cascode transistors is coupled to a first transistor of a pair of bias transistors; and a second transistor of the fourth pair of cascode transistors is coupled to a second transistor of the pair of bias transistors.

Aspect 22: The method of Aspect 21, wherein sources of the pair of bias transistors are coupled to a voltage rail.

Aspect 23: The method of Aspect 21 or 22, wherein: a first transistor of the second pair of cascode transistors is coupled to a drain of a first transistor of the pair of bias transistors; and a second transistor of the second pair of cascode transistors is coupled to a drain of a second transistor of the pair of bias transistors.

Aspect 24: The method according to any of Aspects 21-23, wherein: a drain of a first transistor of the first pair of cascode transistors is coupled to a negative output of the differential output pair; and a drain of a second transistor of the first pair of cascode transistors is coupled to a positive output of the differential output pair.

Aspect 25: The method according to any of Aspects 20-24, wherein: a positive input of a differential input pair is coupled to gates of a first transistor of each of the first pair of input transistors, the second pair of input transistors; and the third pair of input transistors; and a negative input of the differential input pair is coupled to gates of a second transistor of each of the first pair of input transistors, the second pair of input transistors; and the third pair of input transistors.

Aspect 26: The method according to any of Aspects 20-25, wherein: the first pair of cascode transistors, the first pair of input transistors, the second pair of cascode transistors, and the second pair of input transistors are n-channel metal-oxide-semiconductor (NMOS) transistors; and the third pair of input transistors are p-channel metal-oxide-semiconductor (PMOS) transistors.

Aspect 27: The method according to any of Aspects 20-26, further comprising sinking, via a current source, a current from a node coupled to the first pair of input transistors and the second pair of input transistors.

Aspect 28: The method according to any of Aspects 20-27, further comprising sourcing a current, via a current source, to a node coupled to the third pair of input transistors.

Aspect 29: The method according to any of Aspects 20-28, wherein: the first pair of input transistors are part of a first transconductance (Gm) path; the second pair of input transistors are part of a second Gm path; and the third pair of input transistors are part of a third Gm path.

### ADDITIONAL CONSIDERATIONS

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation, and details of the methods and apparatus described above without departing from the scope of the claims.

What is claimed is:

1. An amplifier, comprising:
a first pair of input transistors;
a first pair of cascode transistors coupled in cascode with the first pair of input transistors, respectively;
a second pair of input transistors;
a second pair of cascode transistors coupled in cascode with the second pair of input transistors, respectively; and
a third pair of input transistors coupled to the second pair of cascode transistors, respectively.

2. The amplifier of claim 1, further comprising:
a pair of bias transistors; and
a fourth pair of cascode transistors, wherein:
a first transistor of the fourth pair of cascode transistors is coupled to a first transistor of the pair of bias transistors; and
a second transistor of the fourth pair of cascode transistors is coupled to a second transistor of the pair of bias transistors.

3. The amplifier of claim 2, wherein sources of the pair of bias transistors are coupled to a voltage rail.

4. The amplifier of claim 2, wherein:
a first transistor of the second pair of cascode transistors is coupled to a drain of a first transistor of the pair of bias transistors; and
a second transistor of the second pair of cascode transistors is coupled to a drain of a second transistor of the pair of bias transistors.

5. The amplifier of claim 2, wherein:
a drain of a first transistor of the first pair of cascode transistors is coupled to a negative output of a differential output pair of the amplifier; and
a drain of a second transistor of the first pair of cascode transistors is coupled to a positive output of the differential output pair of the amplifier.

6. The amplifier of claim 1, wherein:
a positive input of a differential input pair is coupled to gates of a first transistor of each of the first pair of input transistors, the second pair of input transistors; and the third pair of input transistors; and
a negative input of the differential input pair is coupled to gates of a second transistor of each of the first pair of input transistors, the second pair of input transistors; and the third pair of input transistors.

7. The amplifier of claim 1, wherein:
the first pair of cascode transistors, the first pair of input transistors, the second pair of cascode transistors, and the second pair of input transistors are n-channel metal-oxide-semiconductor (NMOS) transistors; and
the third pair of input transistors are p-channel metal-oxide-semiconductor (PMOS) transistors.

8. The amplifier of claim 1, further comprising a current source coupled to the first pair of input transistors and the second pair of input transistors.

9. The amplifier of claim 1, further comprising a current source coupled to the third pair of input transistors.

10. The amplifier of claim 1, wherein:
the first pair of input transistors are part of a first transconductance (Gm) path;
the second pair of input transistors are part of a second Gm path; and
the third pair of input transistors are part of a third Gm path.

11. An amplifier, comprising:
a first transconductance (Gm) path coupled between a differential output pair, the first Gm path including a first pair of input transistors and a first pair of cascode transistors coupled in cascode with the first pair of input transistors, respectively;
a second Gm path coupled between the differential output pair, the second Gm path including a second pair of input transistors and a second pair of cascode transistors coupled in cascode with the second pair of input transistors, respectively; and
a third Gm path comprising a third pair of input transistors, the third Gm path being coupled to the second pair of cascode transistors.

12. The amplifier of claim 11, further comprising:
a pair of bias transistors coupled to the second Gm path and the second Gm path; and
a fourth pair of cascode transistors, wherein:
a first transistor of the fourth pair of cascode transistors is coupled to a first transistor of the pair of bias transistors; and
a second transistor of the fourth pair of cascode transistors is coupled to a second transistor of the pair of bias transistors.

13. The amplifier of claim 12, wherein sources of the pair of bias transistors are coupled to a voltage rail.

14. The amplifier of claim 12, wherein:
a first transistor of the second pair of cascode transistors is coupled to a drain of a first transistor of the pair of bias transistors; and
a second transistor of the second pair of cascode transistors is coupled to a drain of a second transistor of the pair of bias transistors.

15. The amplifier of claim 12, wherein:
a drain of a first transistor of the first pair of cascode transistors is coupled to a negative output of the differential output pair of the amplifier; and
a drain of a second transistor of the first pair of cascode transistors is coupled to a positive output of the differential output pair of the amplifier.

16. The amplifier of claim 11, wherein:
a positive input of a differential input pair is coupled to gates of a first transistor of each of the first pair of input transistors, the second pair of input transistors; and the third pair of input transistors; and
a negative input of the differential input pair is coupled to gates of a second transistor of each of the first pair of input transistors, the second pair of input transistors;
and the third pair of input transistors.

17. The amplifier of claim 11, wherein:
the first pair of cascode transistors, the first pair of input transistors, the second pair of cascode transistors, and the second pair of input transistors are n-channel metal-oxide-semiconductor (NMOS) transistors; and
the third pair of input transistors are p-channel metal-oxide-semiconductor (PMOS) transistors.

18. The amplifier of claim 11, further comprising a current source coupled to the first Gm path and the second Gm path.

19. The amplifier of claim 11, further comprising a current source coupled to the third Gm path.

20. A method for signal amplification, comprising:
receiving differential input signals at respective gates of a first pair of input transistors, respective gates of a second pair of input transistors, and respective gates of a third pair of input transistors, wherein:
a first pair of cascode transistors are coupled in cascode with the first pair of input transistors, respectively;
a second pair of cascode transistors are coupled in cascode with the second pair of input transistors, respectively; and
the third pair of input transistors are coupled to the second pair of cascode transistors, respectively; and
generating differential output signals at a differential output pair, respectively, based on the differential input signals, wherein the differential output pair is coupled to the first pair of cascode transistors, respectively.

21. The method of claim 20, wherein:
a first transistor of a fourth pair of cascode transistors is coupled to a first transistor of a pair of bias transistors; and
a second transistor of the fourth pair of cascode transistors is coupled to a second transistor of the pair of bias transistors.

22. The method of claim 21, wherein sources of the pair of bias transistors are coupled to a voltage rail.

23. The method of claim 21, wherein:
a first transistor of the second pair of cascode transistors is coupled to a drain of a first transistor of the pair of bias transistors; and
a second transistor of the second pair of cascode transistors is coupled to a drain of a second transistor of the pair of bias transistors.

24. The method of claim 21, wherein:
a drain of a first transistor of the first pair of cascode transistors is coupled to a negative output of the differential output pair; and
a drain of a second transistor of the first pair of cascode transistors is coupled to a positive output of the differential output pair.

25. The method of claim 20, wherein:
a positive input of a differential input pair is coupled to gates of a first transistor of each of the first pair of input transistors, the second pair of input transistors; and the third pair of input transistors; and
a negative input of the differential input pair is coupled to gates of a second transistor of each of the first pair of input transistors, the second pair of input transistors;
and the third pair of input transistors.

26. The method of claim 20, wherein:
the first pair of cascode transistors, the first pair of input transistors, the second pair of cascode transistors, and the second pair of input transistors are n-channel metal-oxide-semiconductor (NMOS) transistors; and
the third pair of input transistors are p-channel metal-oxide-semiconductor (PMOS) transistors.

27. The method of claim 20, further comprising sinking, via a current source, a current from a node coupled to the first pair of input transistors and the second pair of input transistors.

28. The method of claim 20, further comprising sourcing a current, via a current source, to a node coupled to the third pair of input transistors.

29. The method of claim 20, wherein:
the first pair of input transistors are part of a first transconductance (Gm) path;
the second pair of input transistors are part of a second Gm path; and
the third pair of input transistors are part of a third Gm path.
